(19) United States
(12) Patent Application Publication
(10) Pub. No.: US 2018/0254316 A1
(43) Pub. Date: Sep. 6, 2018

(54) MANUFACTURING METHOD OF METAL-INSULATOR-METAL DEVICE

(71) Applicant: Powerchip Technology Corporation, Hsinchu (TW)

(72) Inventors: Hsin Tai, Taipei City (TW); Po-Cheng Chang, Chiayi County (TW); Hui-Chin Huang, Hsinchu City (TW); Pei-Ting Tou, Kaohsiung City (TW); Ming-Chen Lu, Hsinchu City (TW)

(73) Assignee: Powerchip Technology Corporation, Hsinchu (TW)

(21) Appl. No.: 15/622,080

(22) Filed: Jun. 14, 2017

(30) Foreign Application Priority Data
Mar. 1, 2017 (TW) 106106606

(51) Int. Cl. H01L 49/02; H01L 21/3213; H01L 21/311; H01L 21/02

(52) U.S. Cl. CPC H01L 28/60; H01L 21/32136; H01L 21/31144; H01L 21/02068; H01L 21/32139; H01L 21/31116

(57) ABSTRACT

The invention provides a manufacturing method of a metal-insulator-metal device, including: forming a first metal layer, an insulation layer, and a second metal layer sequentially on a base to form a metal-insulator-metal structure; forming a patterned mask layer on at least a portion of the second metal layer, etching the second metal layer and the insulation layer on which the patterned mask layer is not formed using an etchant without carbon; and cleaning the etched metal-insulator-metal structure using a mixed solution containing oxidants and metal oxide etchants to remove excess polymer remaining on the metal-insulator-metal structure.

### CROSS-REFERENCE TO RELATED APPLICATION

This application claims the priority benefit of Taiwan application serial no. 106106606, filed on Mar. 1, 2017. The entirety of the above-mentioned patent application is hereby incorporated by reference herein and made a part of this specification.

### BACKGROUND OF THE INVENTION

### Field of the Invention

The invention relates to a manufacturing method of a semiconductor device, and more particularly, to a manufacturing method of a metal-insulator-metal (MIM) device.

### Description of Related Art

The metal-insulator-metal device is a commonly used component in a semiconductor device, and the most common application is in a metal-insulator-metal capacitor.

The metal-insulator-metal device is a semiconductor component having a metal-insulator-metal structure. Regarding the manufacturing method of the metal-insulator-metal device, generally, referring to FIG. 1A, after a first metal layer 102, an insulation layer 103, and a second metal layer 104 are sequentially formed on a base 101, an etching step (plasma etching, also dry etching) is performed using a patterned mask layer 105 as a mask and etching gases containing carbon (such as carbon fluoride gas such as CF₄ and C₂H₄). Next, a cleaning step is further performed on an entire metal-insulator-metal structure 100.

However, the steps above produce some issues such as, referring to FIG. 1B, when tantalum, tantalum nitride, or a combination thereof is used as the material of the second metal layer 104, after the etching step is performed, some useless polymer 106 remains on the sidewalls of the second metal layer 104 and the insulation layer 103, which is polymer produced after the reaction of the second metal layer 104 and the insulation layer 103 with the etching gas used in the etching step. In a subsequent cleaning step, these polymers 106 cannot be removed. In a subsequent process, these polymers 106 make the film surface uneven and become the cause for short circuits during electrical connection, such that the performance of the metal-insulator-metal device is affected, and the yield and reliability are worsened as a result.

### SUMMARY OF THE INVENTION

Due to the above issues, the invention provides a manufacturing method of a metal-insulator-metal device, including: forming a first metal layer, an insulation layer, and a second metal layer sequentially on a base to form a metal-insulator-metal structure; forming a patterned mask layer on at least a portion of the second metal layer, etching the second metal layer and the insulation layer on which the patterned mask layer is not formed using an etchant without carbon; and cleaning the etched metal-insulator-metal structure using a mixed solution containing an oxidant and a metal oxide etchant to remove excess polymer remaining on the metal-insulator-metal structure.

According to an embodiment of the invention, in the manufacturing method of the metal-insulator-metal device, the material of the first metal layer and the second metal layer is tantalum, tantalum nitride, or a combination thereof.

According to an embodiment of the invention, in the manufacturing method of the metal-insulator-metal device, after the second metal layer and the insulation layer are etched, an ashing step of removing the patterned mask layer is further included.

According to an embodiment of the invention, in the manufacturing method of the metal-insulator-metal device, the etchant without carbon is an etching gas including chlorine gas (Cl₂) and boron chloride (BCl₃).

According to an embodiment of the invention, in the manufacturing method of the metal-insulator-metal device, the oxidant is at least one selected from the group consisting of hydrogen peroxide and ozone.

According to an embodiment of the invention, in the manufacturing method of the metal-insulator-metal device, the oxidant is a DSP mixed solution of sulfuric acid, hydrogen peroxide, and water.

According to an embodiment of the invention, in the manufacturing method of the metal-insulator-metal device, in the oxidant, based on weight percentage, the ratio of sulfuric acid, hydrogen peroxide, and water is 1:1:10 to 1:1:30.

According to an embodiment of the invention, in the manufacturing method of the metal-insulator-metal device, the metal oxide etchant includes an organic fluorine-containing compound or an inorganic fluorine-containing compound.

According to an embodiment of the invention, in the manufacturing method of the metal-insulator-metal device, the organic fluorine-containing compound is one selected from quaternary ammonium fluorides, and the inorganic fluorine-containing compound is at least one selected from the group consisting of hydrofluoric acid (HF), ammonium fluoride (NH₄F), and hydrofluosilicic acid (H₂SiF₆).

According to an embodiment of the invention, in the manufacturing method of the metal-insulator-metal device, the metal oxide etchant includes hydrofluoric acid.

According to an embodiment of the invention, in the manufacturing method of the metal-insulator-metal device, based on weight percentage, the ratio of the DSP mixed solution and the hydrofluoric acid is between 1000:1 and 100:1.

According to an embodiment of the invention, in the manufacturing method of the metal-insulator-metal device, the pH value of the operating environment thereof is pH<4 or pH>12.

According to an embodiment of the invention, in the manufacturing method of the metal-insulator-metal device, the temperature of the operating environment thereof is in the range of 25° C. to 220° C.

According to an embodiment of the invention, in the manufacturing method of the metal-insulator-metal device, the temperature of the operating environment thereof is less than 130° C.

Based on the above, in the manufacturing method of the metal-insulator-metal device provided in the invention, since an etchant without carbon is used in the etching step, excess carbide is not produced after etching, and at this point, the main source of carbide is the carbohydrate contained in the patterned mask layer itself. As a result, the oxidant used in the cleaning step can sufficiently oxidize these carbides and sufficiently oxidize the polymer produced after the reaction of the second metal layer and the insulation layer with the etching gas. Next, via the fluorine-containing metal oxide etchant, by-products such as the oxidized carbide and polymer can be sufficiently removed, that is, excess polymer remaining on the sidewalls of the second metal layer and the insulation layer can be removed.

Based on the above method, the oxidizing capability can be adjusted by adjusting the temperature and content of the oxidant, and the etching capability can be adjusted by adjusting the pH value and concentration of the fluorine-containing metal oxide etchant. Moreover, carbon fluoride gas with too much etching power such as CF₄ is used as the etchant in current techniques, such that the second metal layer and the insulation layer may be damaged. In this regard, the fluorine-containing metal oxide etchant of the invention does not damage the second metal layer and the insulation layer. Moreover, the manufacturing method of the metal-insulator-metal device of the invention can be performed at room temperature, and therefore manufacturing costs can be reduced. Moreover, compared to plasma etching (dry etching) adopting a carbon fluoride gas such as high-priced CF₄, in the invention, the remaining polymer is removed using wet etching containing an oxidant and a metal oxide etchant in the cleaning step, and the manufacturing costs are also relatively lower.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B are cross-sectional diagrams of the manufacturing process of a metal-insulator-metal device of prior art.

FIG. 2A to FIG. 2D are cross-sectional diagrams of the manufacturing process of a metal-insulator-metal device of an embodiment of the invention.

FIG. 3 is the sidewall situation of a second metal layer and an insulation layer after a cleaning step of example 1 of the invention.

FIG. 4 is the sidewall situation of a second metal layer and an insulation layer after a cleaning step of comparative example 1 of the invention.

FIG. 5 is the sidewall situation of a second metal layer and an insulation layer after a cleaning step of comparative example 2 of the invention.

FIG. 6 is the sidewall situation of a second metal layer and an insulation layer after a cleaning step of comparative example 3 of the invention.

FIG. 7 is the sidewall situation of a second metal layer and an insulation layer after a cleaning step of comparative example 4 of the invention.

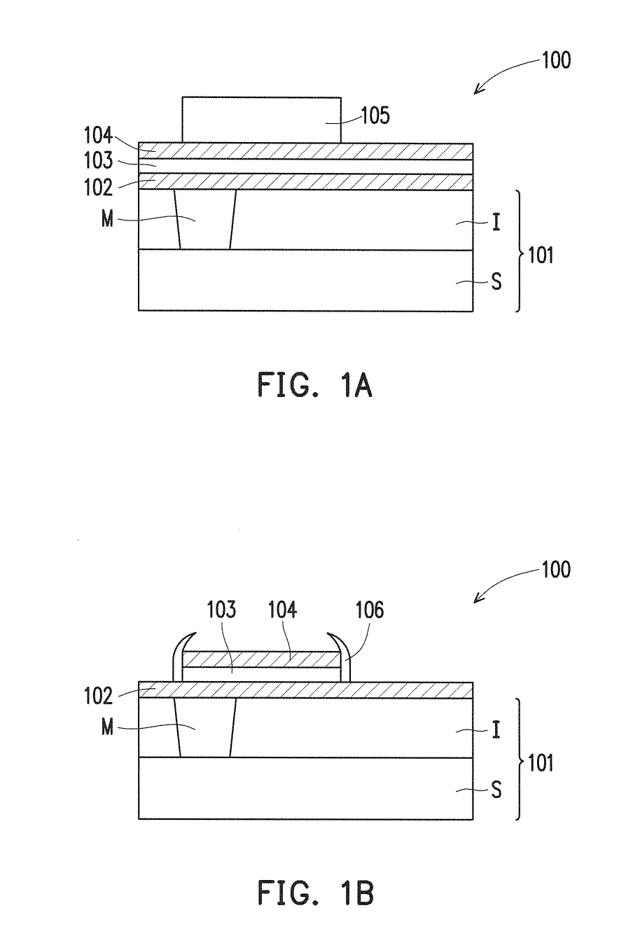

### DESCRIPTION OF THE EMBODIMENTS

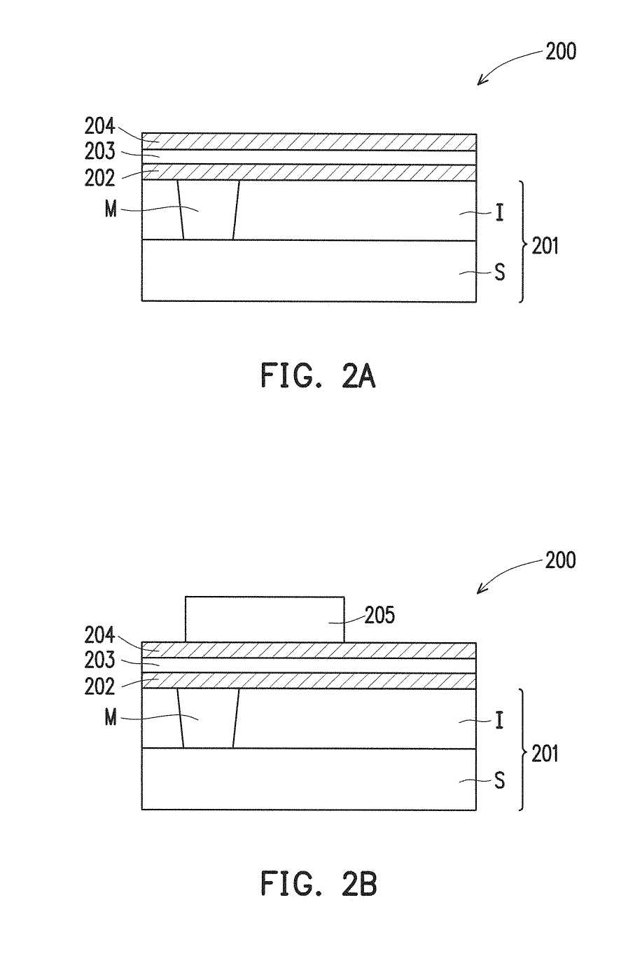

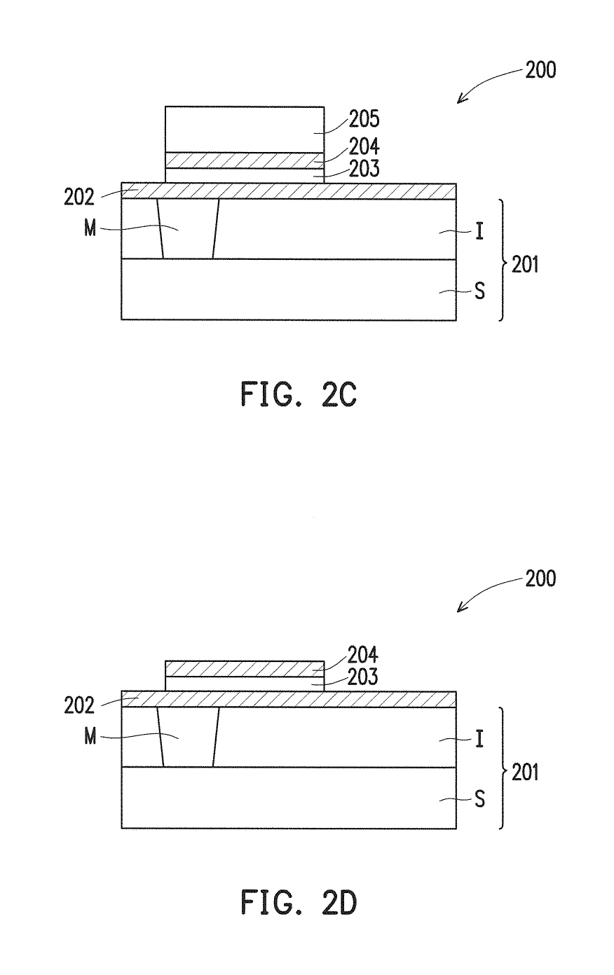

FIG. 2A to FIG. 2D are cross-sectional diagrams of the manufacturing process of a metal-insulator-metal device of an embodiment of the invention.

First, referring to FIG. 2A, a first metal layer 202, an insulation layer 203, and a second metal layer 204 are sequentially formed on a base 201 to form a metal-insulator-metal structure 200.

The base 201 is an ordinary structure in which an inter-metal dielectric (IMD) layer I is disposed on a semiconductor substrate S, and the semiconductor substrate S is, for instance, a silicon substrate or a silicon carbide substrate. A wiring pattern M is disposed in the IMD layer I, the wiring pattern M is, for instance, a plug or a metal wire, and the material of the plug or metal wire is, for instance, a metal having higher conductivity such as gold, silver, or copper. Moreover, a dielectric layer (not shown) is further disposed on the wiring pattern M, and the material of the dielectric layer is, for instance, silicon nitride (SiN) or silicon oxide (SiO₂).

The material of the first metal layer 202 is, for instance, tantalum (Ta), tantalum nitride (TaN), or a combination thereof.

The method of forming the first metal layer 202 is, for instance, a vacuum thin film deposition method such as chemical vapor deposition (CVD), physical vapor deposition (PVD), or atomic layer deposition (ALD).

The material of the insulation layer 203 is an ordinary high-dielectric constant material such as silicon nitride (SiN), tantalum oxide (Ta₂Os), aluminum oxide (Al₂O₃), hafnium aluminum oxide (HfₓAl_{y}O), hafnium oxide (HfO₂), or titanium oxide (TiO₂).

The method of forming the insulation layer 203 is, for instance, a vacuum thin film deposition method such as chemical vapor deposition (CVD), physical vapor deposition (PVD), or atomic layer deposition (ALD).

The material of the second metal layer 204 is, for instance, tantalum (Ta), tantalum nitride (TaN), or a combination thereof.

The method of forming the second metal layer 204 is, for instance, a vacuum thin film deposition method such as chemical vapor deposition (CVD), physical vapor deposition (PVD), or atomic layer deposition (ALD).

Then, referring to FIG. 2B, a patterned mask layer 205 is formed on the second metal layer 204. The forming method of the patterned mask layer 205 includes forming a common positive photoresist or negative photoresist on the second metal layer 204 and performing an ordinary exposure step and developing step according to the desired wiring pattern.

The light source used in the exposure step is, for instance, i-ray (365 nm), h-ray (405 nm), g-ray (436 nm), ArF light source (193 nm), KrF light source (248 nm), or other light sources having suitable wavelengths. The developing solution used in the developing step is, for instance, an alkaline developing solution or an organic developing solution, the alkaline developing solution is, for instance, an aqueous solution such as sodium hydroxide, sodium bicarbonate, or tetramethylazanium hydroxide (TMAH), and the organic developing solution is, for instance, an organic solution such as alcohol, ketone, or ester.

The developing solution can remove the exposed/not exposed patterned mask layer 205. For instance, when a positive photoresist is used, the exposed portion is dissolved in the developing solution, and when a negative photoresist is used, the portion not exposed is dissolved in the developing solution. That is, by using a positive photoresist or a negative photoresist and removing the exposed/not exposed patterned mask layer 205 using a suitable developing solution, the patterned mask layer 205 having the desired wiring pattern is formed.

Next, referring to FIG. 2C, an etching step is performed on the metal-insulator-metal structure 200 using the patterned mask layer 205 as a mask, wherein the second metal layer 204 and the insulation layer 203 on which the patterned mask layer 205 is not formed are etched using an etchant without carbon. At this point, since the portion of the second metal layer 204 and the insulation layer 203 on which the patterned mask layer 205 is not formed is not protected and is etched, only the portion protected by the patterned mask layer 205 remains.

Next, referring to FIG. 2D, a cleaning step is performed on the etched metal-insulator-metal structure 200 using a mixed solution containing an oxidant and a metal oxide etchant to remove the patterned mask layer 205 and the polymer (not shown) remaining on the sidewalls of the second metal layer 204 and the insulation layer 203.

Since an etchant without carbon is used in the etching step, excess carbide is not produced after etching, that is, only the patterned mask layer 205 itself substantially contains carbide. Then, cleaning is performed using a mixed solution containing an oxidant and a metal oxide etchant in the cleaning step. The oxidant can sufficiently oxidize the carbide contained in the patterned mask layer 205 and sufficiently oxidize the polymer produced after the reaction of the second metal layer 204 and the insulation layer 203 with the etching gas, such that the metal oxide etchant can sufficiently remove, for instance, oxidized carbide and polymer, and as a result, polymer does not remain on the sidewalls of the second metal layer 204 and the insulation layer 203.

That is, after the etching step and the cleaning step, since residual polymer is not present on the sidewalls of the second metal layer 204 and the insulation layer 203, if a film is further formed on the metal-insulator-metal structure 200, then an even and flat film surface can be formed. Moreover, short circuit caused by the polymer in a subsequent process can be prevented so as to avoid affecting product yield and reliability. Therefore, the yield and reliability of the metal-insulator-metal device formed by the etching step and the cleaning step above are excellent.

Moreover, an ashing step (not shown) removing the patterned mask layer 205 can also be optionally included after the etching of the second metal layer 204 and the insulation layer 203 to first oxidize the carbide contained in the patterned mask layer 205 and reduce the carbide amount to be oxidized by the oxidant in a subsequent cleaning step. As a result, the sufficient oxidation of the polymer produced by the second metal layer 204 and the insulation layer 203 can be facilitated, and therefore the removal of the polymer after oxidation can be facilitated.

Moreover, an ashing step can be optionally performed according to the temperature of the operating environment. If the temperature of the operating environment is 130° C. or more, then the oxidizing capability of the oxidant used in the cleaning step is sufficient, and the oxidizing capability thereof is sufficient for the oxidation of the carbide contained in the patterned mask layer 205 and the polymer produced by the second metal layer 204 and the insulation layer 203. That is, if the temperature of the operating environment is 130° C. or more, then even if the ashing step is not performed, the carbide and polymer can still be sufficiently removed in the cleaning step. If the operating temperature is less than 130° C., then the ashing step is preferably included.

In the etching step, the etchant without carbon is, for instance, an etching gas including chlorine gas and boron chloride.

In the cleaning step above, the oxidant is a commonly-used oxidant in the art, and is, for instance, at least one selected from the group consisting of hydrogen peroxide and ozone, and is preferably a mixed solution of sulfuric acid, hydrogen peroxide, and water called DSP mixed solution. In the DSP mixed solution, based on weight percentage, the ratio of sulfuric acid, hydrogen peroxide, and water is preferably 1:1:10 to 1:1:30.

By using the DSP mixed solution, the carbide contained in the patterned mask layer 205 and the polymer produced by the second metal layer 204 and the insulation layer 203 can be more sufficiently oxidized, such that the sufficient removal of the carbide and the polymer by the metal oxide etchant can be facilitated more.

In the cleaning step, the metal oxide etchant preferably includes an organic fluorine-containing compound or an inorganic fluorine-containing compound. Via the organic fluorine-containing compound or inorganic fluorine-containing compound, the carbide contained in the oxidized patterned mask layer 205 and the polymer produced by the second metal layer 204 and the insulation layer 203 can be sufficiently removed.

The organic fluorine-containing compound is, for instance, one selected from quaternary ammonium fluorides, and the inorganic fluorine-containing compound is at least one selected from the group consisting of hydrofluoric acid, ammonium fluoride, and hydrofluosilicic acid.

Moreover, the metal oxide etchant is more preferably hydrofluoric acid.

In the cleaning step, the method of adjusting the oxidation capability of the oxidant can include setting the temperature of the operating environment thereof in the range of 25° C. and 220° C. Since the method can be performed at room temperature, a heating apparatus is not needed for heating, and therefore unnecessary energy waste can be avoided and operating cost can be reduced. Moreover, if the temperature of the operating environment is 130° C. or more, then as described above, the oxidation capability of the oxidant is sufficient, and an ashing step can be omitted such that operating time can be reduced.

In the cleaning step, the method of adjusting the etching capability of the metal oxide etchant can include adjusting the pH value and the concentration of the metal oxide etchant. For instance, the pH value of the metal oxide etchant is preferably pH<4 or pH>12, and therefore the carbide contained in the oxidized patterned mask layer 205 and the polymer produced by the second metal layer 204 and the insulation layer 203 can be sufficiently removed.

Moreover, the etching capability of the metal oxide etchant can also be adjusted by adjusting the ratio of the oxidant and the metal oxide etchant. For instance, when the DSP mixed solution is used as the oxidant and hydrofluoric acid is used as the metal oxide etchant, based on weight percentage, the ratio of the DSP mixed solution and the hydrofluoric acid is preferably in the range of 1000:1 to 100:1. If the ratio is greater than 1000:1, then the concentration of hydrofluoric acid is too low, such that the carbide contained in the oxidized patterned mask layer 205 and the polymer produced by the second metal layer 204 and the insulation layer 203 cannot be sufficiently removed. If the ratio is less than 100:1, then the concentration of hydrofluoric acid is too high, such that the second metal layer 204 and the insulation layer 203 are damaged.

In the following, the invention is described in detail via examples, but the invention is not limited to these examples.

### EXAMPLES

### Example 1

A first metal layer, an insulation layer, and a second metal layer were sequentially laminated to form a metal-insulator-metal structure, and a patterned mask layer was formed on the second metal layer, wherein the material of the first metal layer and the second metal layer is tantalum, and the material of the insulation layer is silicon nitride.

Next, an etching gas containing chlorine gas and boron chloride was used in an etching step to etch the second metal layer and the insulation layer on which the patterned mask layer was not formed.

Next, an ashing step was performed on the etched metal-insulator-metal structure in a temperature range of the operating environment of less than 130° C.

Next, in the cleaning step, the ashed metal-insulator-metal structure was cleaned using a mixed solution containing a DSP solution and hydrofluoric acid in a temperature range of 25° C. to 220° C. of the operating environment and a pH value of pH<4 or pH>12. The DSP solution is a mixed solution of sulfuric acid, hydrogen peroxide, and water, and based on weight percentage, the ratio of sulfuric acid, hydrogen peroxide, and water is 1:1:10 to 1:1:30. Moreover, the ratio of the DSP solution and the hydrofluoric acid is between 1000:1 and 100:1.

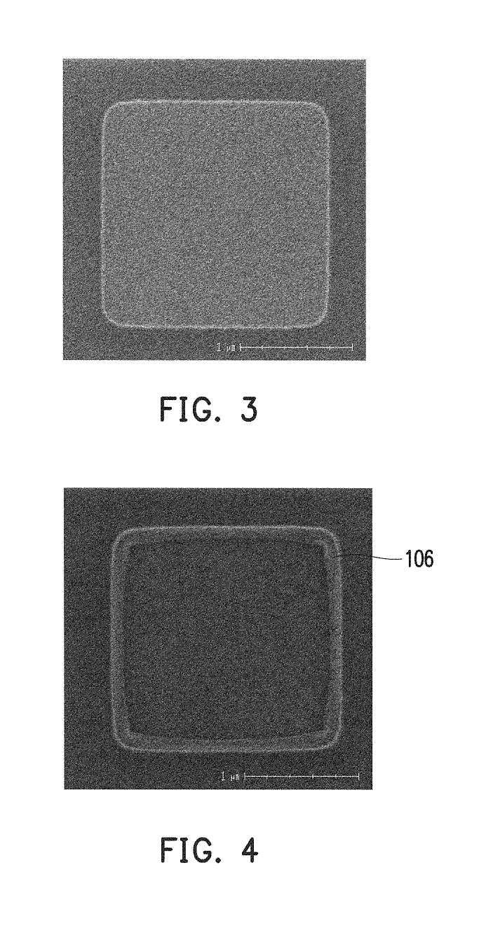

Via the steps above, the DSP solution can sufficiently oxidize the carbide in the patterned mask layer and sufficiently oxidize the polymer produced after the reaction of the second metal layer and the insulation layer with the etching gas, such that hydrofluoric acid can sufficiently remove the oxidized carbide and polymer. The results are as shown in FIG. 3, and useless polymer does not remain on the sidewalls of the second metal layer and the insulation layer.

### Comparative Example 1

An etching gas including chlorine gas and ethylene (C₂H₄) was used in the etching step, that is, the etchant thereof contains carbon. Other than this, the same operation as example 1 was performed. The results are as shown in FIG. 4, and useless polymer still remained on the sidewalls of the second metal layer and the insulation layer.

### Comparative Example 2

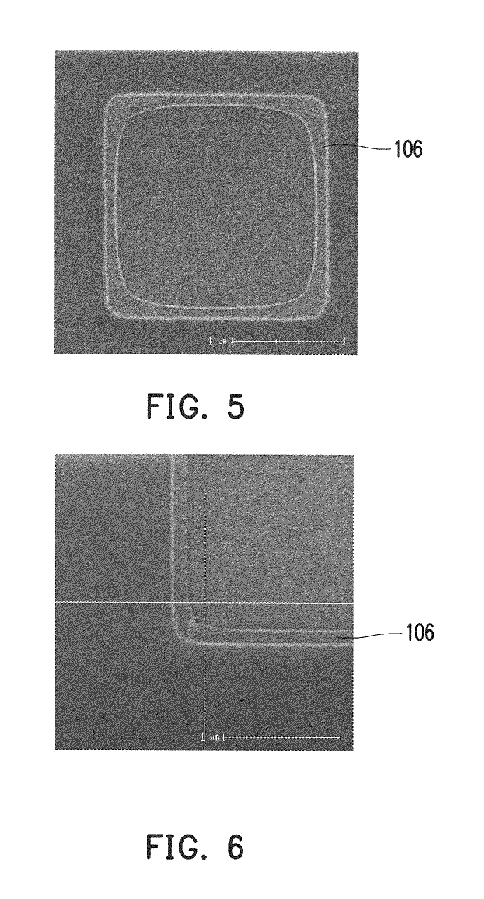

The ratio of the DSP solution and the hydrofluoric acid in the cleaning step was 10000:1. Other than this, the same operation as example 1 was performed. The results are as shown in FIG. 5, and useless polymer still remained on the sidewalls of the second metal layer and the insulation layer.

### Comparative Example 3

The cleaning solution in the cleaning step was EKC265 (product name, made by DuPont) solution. Other than this, the same operation as example 1 was performed. The results are as shown in FIG. 6, and useless polymer still remained on the sidewalls of the second metal layer and the insulation layer.

### Comparative Example 4

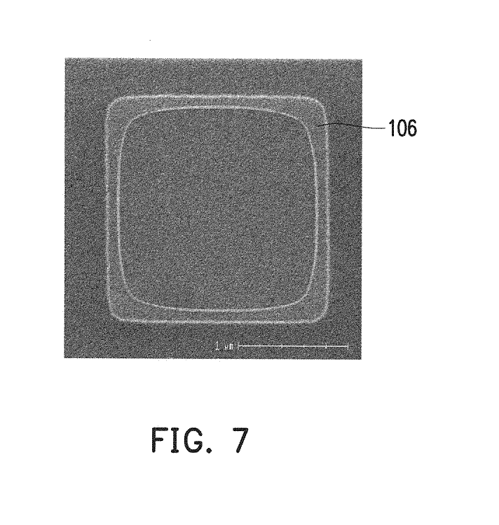

The cleaning solution in the cleaning step was ST250 (product name, made by Advanced Technology Materials, Inc. (ATMI)) solution, and the pH value of the operating environment was set to 8. Other than this, the same operation as example 1 was performed. The results are as shown in FIG. 7, and useless polymer still remained on the sidewalls of the second metal layer and the insulation layer.

It can be known according to example 1 and comparative example 1 to comparative example 4 that, since an etchant containing carbon was used in comparative example 1, excess carbide was produced after etching. Even though the oxidant and the metal oxide etchant used in the cleaning step thereof were both the same as example 1, the carbide was excessive, such that the oxidant and the metal oxide etchant could not sufficiently oxidize and remove the carbide and the polymer on the sidewalls of and the second metal layer and the insulation layer.

The difference between comparative example 2 and example 1 is only that the ratio of the DSP solution and hydrofluoric acid used in comparative example 2 is 10000:1, and the ratio is outside the range of 1000:1 to 100:1 defined in the invention. That is, the concentration of the hydrofluoric acid is too low such that the polymer on the sidewalls of the second metal layer and the insulation layer cannot be sufficiently removed.

Even though an etchant without carbon is used in comparative example 3, the cleaning solution (EKC265) thereof does not contain an oxidant and a metal oxide etchant, and therefore the polymer on the sidewalls of the second metal layer and the insulation layer cannot be sufficiently removed.

Moreover, even though an etchant without carbon is used in comparative example 4, the cleaning solution (ST250) thereof is a solution containing a metal oxide etchant without an oxidant, and therefore the polymer on the sidewalls of the second metal layer and the insulation layer cannot be oxidized. Moreover, the pH value of the operating environment of comparative example 4 is 8, which is outside the range of pH<4 or pH>12 defined in the invention. Based on the above factors, in comparative example 4, the polymer on the sidewalls of the second metal layer and the insulation layer cannot be sufficiently removed.

Based on the above, in the invention, by using an etchant without carbon in the etching step, excess carbide is not produced after etching. Then, cleaning is performed using a mixed solution containing an oxidant and a metal oxide etchant in the cleaning step at a temperature of the operating environment of 25° C. to 220° C. and a pH value of pH<4 or pH>12. The oxidant can sufficiently oxidize the carbide contained in the patterned mask layer, and can sufficiently oxidize the polymer produced after the reaction of the second metal layer and the insulation layer with the etching gas. Then, the metal oxide etchant can sufficiently remove the oxidized carbide and polymer such that polymer does not remain on the sidewalls of the second metal layer and the insulation layer. The desired technical effect of the present application is thus achieved.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A manufacturing method of a metal-insulator-metal device, comprising:
forming a first metal layer, an insulation layer, and a second metal layer sequentially on a base to form a metal-insulator-metal structure;
forming a patterned mask layer on at least a portion of the second metal layer;
etching the second metal layer and the insulation layer on which the patterned mask layer is not formed using an etchant without carbon; and
cleaning the etched metal-insulator-metal structure using a mixed solution containing an oxidant and a metal oxide etchant to remove excess polymer remaining on the metal-insulator-metal structure.

2. The manufacturing method of the metal-insulator-metal device of claim 1, wherein a material of the first metal layer and the second metal layer is tantalum, tantalum nitride, or a combination thereof.

3. The manufacturing method of the metal-insulator-metal device of claim 1, further comprising, after the second metal layer and the insulation layer are etched, an ashing step of removing the patterned mask layer.

4. The manufacturing method of the metal-insulator-metal device of claim 1, wherein the etchant without carbon is an etching gas comprising chlorine gas and boron chloride.

5. The manufacturing method of the metal-insulator-metal device of claim 1, wherein the oxidant is at least one selected from the group consisting of hydrogen peroxide and ozone.

6. The manufacturing method of the metal-insulator-metal device of claim 1, wherein the oxidant is a DSP mixed solution of a sulfuric acid, a hydrogen peroxide, and a water.

7. The manufacturing method of the metal-insulator-metal device of claim 6, wherein in the oxidant, based on a weight percentage, a ratio of the sulfuric acid, the hydrogen peroxide, and the water is 1:1:10 to 1:1:30.

8. The manufacturing method of the metal-insulator-metal device of claim 1, wherein the metal oxide etchant comprises an organic fluorine-containing compound or an inorganic fluorine-containing compound.

9. The manufacturing method of the metal-insulator-metal device of claim 8, wherein the organic fluorine-containing compound is one selected from quaternary ammonium fluorides, and the inorganic fluorine-containing compound is at least one selected from the group consisting of hydrofluoric acid, ammonium fluoride, and hydrofluosilicic acid.

10. The manufacturing method of the metal-insulator-metal device of claim 1, wherein the metal oxide etchant comprises hydrofluoric acid.

11. The manufacturing method of the metal-insulator-metal device of claim 1, wherein
the oxidant is a DSP mixed solution of a sulfuric acid, a hydrogen peroxide, and a water, and based on a weight percentage, a ratio of the sulfuric acid, the hydrogen peroxide, and the water is between 1:1:10 and 1:1:30, and
the metal oxide etchant comprises hydrofluoric acid.

12. The manufacturing method of the metal-insulator-metal device of claim 11, wherein based on a weight percentage, a ratio of the DSP mixed solution and the hydrofluoric acid is between 1000:1 and 100:1.

13. The manufacturing method of the metal-insulator-metal device of claim 1, wherein a pH value of an operating environment thereof is pH<4 or pH>12.

14. The manufacturing method of the metal-insulator-metal device of claim 1, wherein a temperature of an operating environment thereof is between 25° C. and 220° C.

15. The manufacturing method of the metal-insulator-metal device of claim 3, wherein a temperature of an operating environment thereof is less than 130° C.
